(19) United States
(12) Patent Application Publication
(10) Pub. No.: US 2023/0247376 A1
(43) Pub. Date: Aug. 3, 2023

(54) A Fully Differential Piezoelectric Microphone and Amplifier System for Cochlear Implants and Other Hearing Devices

(71) Applicants: Massachusetts Institute of Technology, Cambridge, MA (US); Massachusetts Eye and Ear Infirmary, Boston, MA (US); The Trustees of Columbia University in the City of New York, New York, NY (US)

(72) Inventors: Jeffrey H. Lang, Sudbury, MA (US); Aaron J. Yeiser, Allston, MA (US); Hideko Heidi Nakajima, Cambridge, MA (US); Ioannis Kymissis, New York, NY (US); Elizabeth Olson, New York, NY (US); Christopher I. McHugh, Boston, MA (US); Lukas Graf, Berlingen (CH)

(21) Appl. No.: 18/104,518

(22) Filed: Feb. 1, 2023

Related U.S. Application Data
(60) Provisional application No. 63/306,206, filed on Feb. 3, 2022.
(60) Provisional application No. 63/345,183, filed on May 24, 2022.

(51) Int. Cl. H04R 25/00; H04R 17/00; H05K 1/18

(52) U.S. Cl. CPC H04R 25/606; H04R 17/00; H05K 1/189; H04R 25/609; H04R 2225/57

(57) ABSTRACT

A piezoelectric sensor and amplifier for use with an auditory aid device are disclosed. The piezoelectric sensor includes a top sensor and a bottom sensor disposed on opposite surfaces of a flex printed circuit board. The top and bottom sensors are made of a piezoelectric material, such as PVDF. Further, the piezoelectric sensor is adapted to be implanted into a subject's ear, where the piezoelectric sensor is cantilevered with the free, or distal end, touching the umbo. The proximal end is held in place by a support that is affixed to the ear. Additionally, the piezoelectric sensor is shaped so that the width of the distal end is less than the width at the proximal end. Further, the piezoelectric sensor generates differential signals, which are then amplified using a differential amplifier circuit.

This application claims priority of U.S. Provisional Patent Application Ser. No. 63/306,206, filed Feb. 3, 2022 and U.S. Provisional Patent Application Ser. No. 63/345,183, filed May 24, 2022, the disclosures of which are herein incorporated by reference in their entireties.

This invention was made with government support under DC016874 awarded by the National Institutes of Health. The government has certain rights in the invention.

### FIELD

This disclosure describes a piezoelectric microphone and amplifier system useful for cochlear implants.

### BACKGROUND

Hearing loss is a common problem among humans. This may be caused by deterioration or damage to the bones in the middle ear, also known as the ossicular chain. This may be treated by a middle ear implant that emulates the function of the ossicular chain. Alternatively, the condition may be treated by a cochlear implant which generates electrical signals that are connected to the auditory nerve. Hearing loss may also be caused by damage to the cochlea. In this case, the condition is treated by the cochlear implant described above.

The development and widespread adoption of fully implantable hearing devices is hindered by the lack of suitable implantable microphones. Despite decades of research, current implantable microphone candidates suffer from some combination of poor sensitivity, reliability, and susceptibility to electromagnetic interference.

Therefore, it would be advantageous if there were a piezoelectric sensor and amplifier system that achieved sensitivity comparable to commercially available hearing aid microphones, adequate EMI rejection, linear mechanical impedance, and a robust and straightforward implantation procedure.

### SUMMARY

A piezoelectric sensor and amplifier for use with an auditory aid device are disclosed. The piezoelectric sensor includes a top sensor and a bottom sensor disposed on opposite surfaces of a flex printed circuit board. The top and bottom sensors are made of a piezoelectric material, such as PVDF. Further, the piezoelectric sensor is adapted to be implanted into a subject's ear, where the piezoelectric sensor is cantilevered with the free, or distal end, touching the umbo. The proximal end is held in place by a support that is affixed to a bone in the ear. Additionally, the piezoelectric sensor is shaped so that the width of the distal end is less than the width at the proximal end. Further, the piezoelectric sensor generates differential signals, which are then amplified using a differential amplifier circuit.

According to one embodiment, an implantable auditory aid device is disclosed. The device comprises a piezoelectric sensor; and a platform having an anchor to attach to a subject's ear bone and a support to hold the piezoelectric sensor such that the piezoelectric sensor is cantilevered; wherein the piezoelectric sensor comprises: a flex printed circuit board; a top sensor disposed on a first surface of the flex printed circuit board; and a bottom sensor disposed on an opposite second surface of the flex printed circuit board; the top sensor and bottom sensor made of a piezoelectric material.

In some embodiments, the top sensor and the bottom sensor are shorter in a length direction than the flex printed circuit board and each have a proximal end near an attachment to the support and a distal end, wherein the distal end of one of the sensors is adapted to contact an umbo in the subject's ear. In some embodiments, the proximal end is wider than the distal end. In certain embodiments, the top sensor and the bottom sensor are each shaped as a triangle, trapezoid or pentagon. In certain embodiments, the top sensor and the bottom sensor are each shaped as a hexagon.

In some embodiments, silver epoxy is disposed between the top sensor and the first surface of the flex printed circuit board to form a positive electrode; silver epoxy is disposed between the bottom sensor and the opposite second surface of the flex printed circuit board to form a negative electrode; and the positive electrode and the negative electrode are connected to pads on the flex printed circuit board. In certain embodiments, an exposed surface of the top sensor and the exposed surface of the bottom sensor are covered with a conductive coating, which serves as a ground plane and is connected to a ground pad on the flex printed circuit board. In some embodiments, signals from the positive electrode and the negative electrode are used as inputs to a differential amplifier.

In some embodiments, a conductive layer is evaporated on the first surface of the flex printed circuit board to form a positive electrode and the conductive layer is evaporated on the opposite second surface of the flex printed circuit board to form a negative electrode; wherein the top sensor and the bottom sensor are each attached to the conductive layer using an adhesive and the positive electrode and the negative electrode are connected to pads on the flex printed circuit board. In certain embodiments, an exposed surface of the top sensor and the exposed surface of the bottom sensor are covered with a conductive coating, which serves as a ground plane and is connected to a ground pad on the flex printed circuit board. In some embodiments, signals from the positive electrode and the negative electrode are used as inputs to a differential amplifier.

In some embodiments, a conductive layer is sputtered on the first surface of the flex printed circuit board to form a positive electrode and the conductive layer is sputtered on the opposite second surface of the flex printed circuit board to form a negative electrode; wherein the top sensor and the bottom sensor are each attached to the conductive layer using an adhesive and the positive electrode and the negative electrode are connected to pads on the flex printed circuit board. In some embodiments, an exposed surface of the top sensor and the exposed surface of the bottom sensor are sputtered with a conductive coating, which serves as a ground plane and is connected to the flex printed circuit board using a conductive ink. In some embodiments, signals from the positive electrode and the negative electrode are used as inputs to a differential amplifier.

In some embodiments, the platform comprises the anchor, for attachment to the subject's ear bone; and the support disposed at a distal end of an arm; wherein the anchor and the support are separate components. In certain embodiments, a ball joint is disposed on the anchor and a ball disposed on a proximal end of the arm, wherein the arm is rigidly attached to the ball joint using a set screw. In certain embodiments, the anchor comprises one or more anchor holes, and the ball joint comprises a threaded hole.

According to another embodiment, a method of implanting the implantable auditory aid device described above is disclosed. The method comprises attaching the anchor to a bone in a mastoid cavity by inserting screws through the one or more anchor holes; guiding the piezoelectric sensor through a facial recess of the subject, while the piezoelectric sensor is attached to the support; and affixing the arm to the anchor by tightening a set screw in the threaded hole.

In some embodiments, after tightening the set screw, the piezoelectric sensor contacts an umbo. In some embodiments, the method comprises inserting the set screw in the threaded hole prior to guiding the piezoelectric sensor. In some embodiments, the positioning of the piezoelectric sensor is confirmed using an endoscope. In some embodiments, the positioning of the piezoelectric sensor is confirmed by delivering a sound to an ear canal and monitoring an output of the piezoelectric sensor.

In some embodiments, the top sensor comprises a first plurality of piezoelectric layers stacked on the first surface of the flex printed circuit board; and the bottom sensor comprises a second plurality of piezoelectric layers stacked on the opposite second surface of the flex printed circuit board. In some embodiments, a conductive layer is disposed on both surfaces of each piezoelectric layer, wherein the conductive layers serve as electrodes or ground layers. In some embodiments, outputs from the electrodes disposed on the first surface of the flex printed circuit board are arranged in parallel such that charges induced on each of the first plurality of piezoelectric layers are summed. In some embodiments, the conductive layer on a first surface of a piezoelectric layer is also the conductive layer on a second surface of an adjacent piezoelectric layer, and a conductive epoxy is used to affix the piezoelectric layer and the adjacent piezoelectric layer. In some embodiments, epoxy is disposed between the conductive layer on a first surface of a piezoelectric layer and the conductive layer on a second surface of an adjacent piezoelectric layer. In some embodiments, the first plurality of piezoelectric layers is equal to the second plurality of piezoelectric layers.

### BRIEF DESCRIPTION OF THE DRAWINGS

For a better understanding of the present disclosure, reference is made to the accompanying drawings, in which like elements are referenced with like numerals, and in which:

FIG. 1 shows a cross-section of a human ear;

FIG. 2 is a block diagram showing an auditory aid device;

FIG. 3 shows the placement of the piezoelectric sensor within the ear;

FIG. 4 shows a perspective view of the piezoelectric sensor;

FIG. 5A shows the cross-section of the piezoelectric sensor of FIG. 4;

FIG. 5B shows the cross-section of the piezoelectric sensor according to another embodiment;

FIG. 5C shows the cross-section of the piezoelectric sensor according to a third embodiment, where there are multiple piezoelectric layers on each surface of the flex printed circuit board;

FIG. 6 shows the amplifier circuit according to one embodiment;

FIG. 7 shows one embodiment of the platform using a ball joint; and

FIG. 8 shows the implanted anchor in a subject's ear.

### DETAILED DESCRIPTION

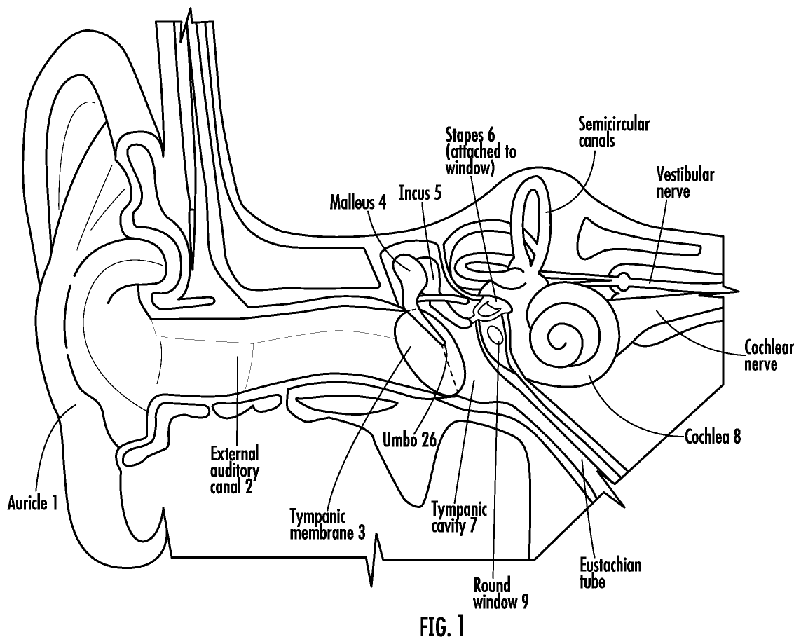

FIG. 1 shows a cross-section of a human ear, which includes an outer ear, a middle ear and an inner ear. The outer ear is made up of those parts up to and including the ear drum, or tympanic membrane. This includes the outer ear or auricle 1, the external auditory canal 2, and the tympanic membrane 3. The middle ear includes the ossicular chain, which is made up of the malleus 4, the incus 5 and the stapes 6. The ossicular chain is located within the tympanic cavity 7. The malleus 4 contacts the tympanic membrane 3 at the umbo 26. The umbo 26 is the area where a section of the malleus 4 is firmly attached to the tympanic membrane 3. This occurs at the location where the tympanic membrane 3 is most depressed, as viewed from within the external auditory canal 2. The inner ear includes the cochlea 8. The middle ear is separated from the inner ear by the round window 9 and the oval window.

Sound pressure enters the external auditory canal 2 and causes vibrations of the tympanic membrane 3. The motion of the tympanic membrane 3 causes motion of the ossicular chain. The stapes 6 causes vibrations to occur at the oval window. The movement of the oval window causes motion of the fluid within the cochlea 8. The motion of the fluid causes motion of hair cells within the cochlea 8, which then generates electrical signals, which are interpreted as sound by the brain.

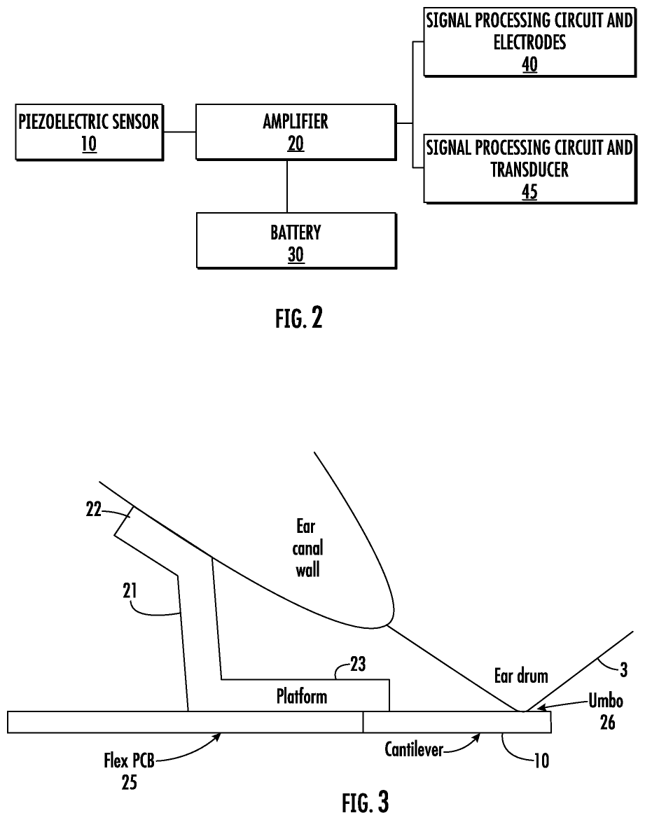

FIG. 2 shows a block diagram of an auditory aid device. The auditory aid device includes a piezoelectric sensor 10, which is used to convert motion of the umbo 26 into electrical signals. The output from the piezoelectric sensor 10 is coupled to an amplifier 20, which is used to amplify the electrical signal received by the piezoelectric sensor 10, while ideally maintaining the signal to noise ratio. The amplifier 20 may be powered by a battery 30. The output of the amplifier 20, which is an analog signal or signals, can then be used for either a middle ear implant or a cochlear implant.

For a cochlear implant, the output of the amplifier 20 is coupled to signal processing circuit and electrodes 40. The signal processing circuit may convert the output from the amplifier 20 to a digital signal, which is then processed. This processing may include filtering and other functions. The output from the signal processing circuit then feeds one or more electrodes which are in communication with the auditory nerve.

For a middle ear implant, the output of the amplifier 20 is coupled to signal processing circuit and transducer 45. The signal processing circuit may convert the output from the amplifier to a digital signal, which is then processed. This processing may include filtering and other functions. The output from the signal processing circuit then feeds a transducer, which may be in communication with the oval window or the round window 9.

The present disclosure is directed toward the design and structure of the piezoelectric sensor 10 and the amplifier 20. Those skilled in the art will understand how to utilize the output of the amplifier 20 to create the signal processing circuit needed for a cochlear or middle ear implant.

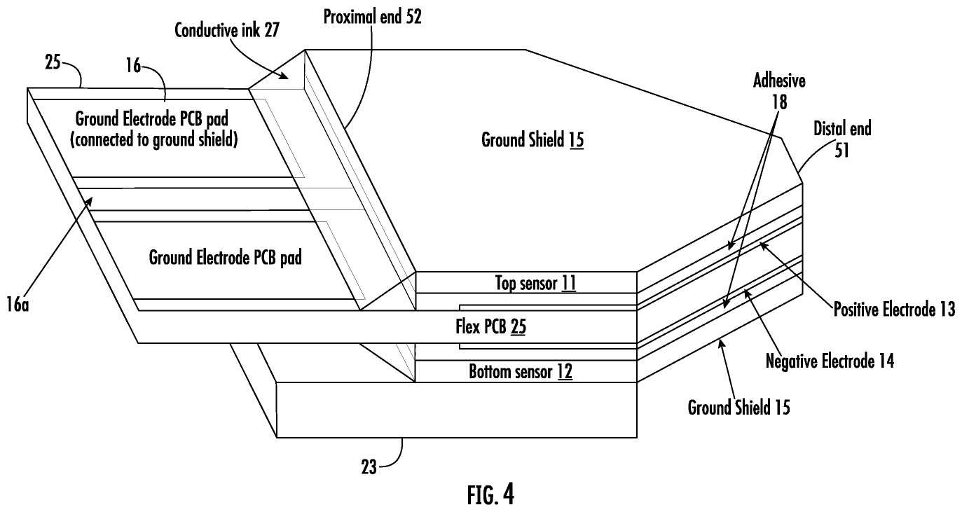

FIG. 3 shows the placement of the piezoelectric sensor 10 within the ear. The piezoelectric sensor 10 is formed as a cantilever, denoting that it is fixed at its proximal end and floating at its distal end. The distal end is in contact with the umbo 26. The proximal end is in contact with a flex printed circuit board 25. In some embodiments, the amplifier 20 may be disposed on a separate printed circuit board. The output from the flex printed circuit board 25 is carried to an external component that contains the amplifier 20 using twisted pair wires or small coaxial cables. The piezoelectric sensor 10 is held in place by a platform 21. The platform 21 has an anchor 22 which is attached to a bone in the ear at one or a plurality of different locations. For example, the anchor 22 may be attached to the bony wall of the middle ear cavity biased towards resting on the promontory. The platform 21 also has a support 23 that is used to support with piezoelectric sensor 10. Importantly, the piezoelectric sensor 10 extends beyond the support 23 so as to ensure that the piezoelectric sensor 10 is capable of bending.

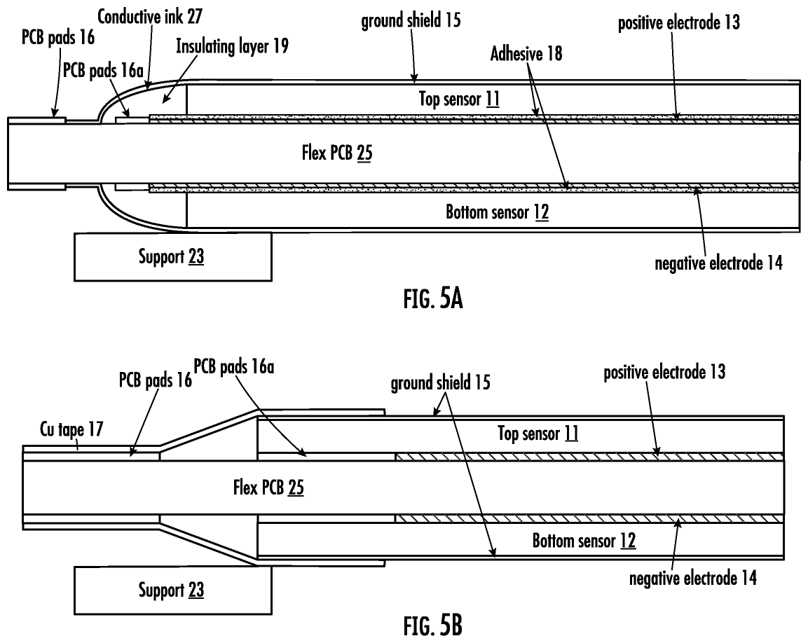

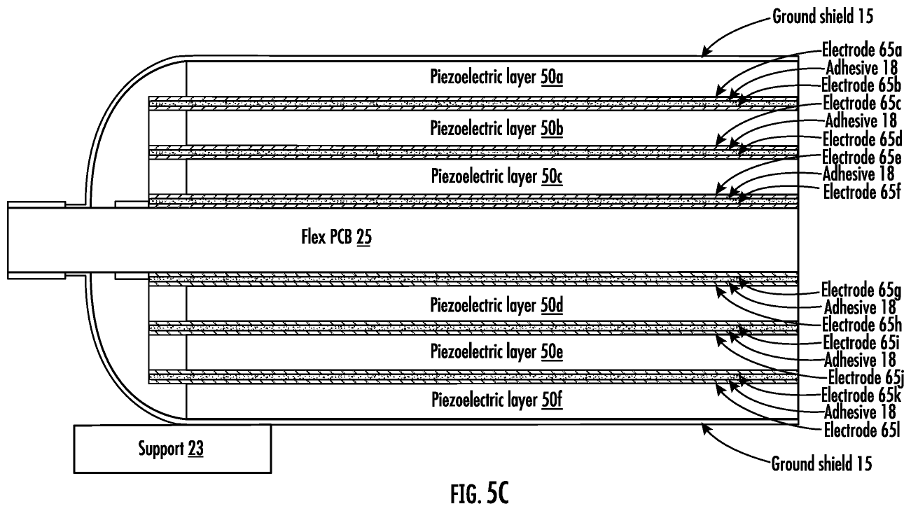

FIG. 4 shows a perspective view of the piezoelectric sensor 10 according to one embodiment. FIG. 5A shows a cross-sectional view of the piezoelectric sensor 10 according to this embodiment. Importantly, the piezoelectric sensor 10 is wider at the proximal end 52 (the end that is supported by the support 23) than at the distal end 51 (where the piezoelectric sensor 10 contacts the umbo 26). In this disclosure, thickness is defined as the direction through the layers of the piezoelectric sensor 10. Length is defined as the distance from the proximal end 52 to the distal end 51 and width is defined as the direction perpendicular to the length and thickness. In certain embodiments, the piezoelectric sensor 10 may taper from its proximal end 52 to its distal end 51. For example, the piezoelectric sensor 10 may be formed as a triangle or a trapezoid. In certain embodiments, it may be advantageous for the shape of the piezoelectric sensor 10 to be symmetric in the width direction. In other words, if an axis is created from the midpoint of the proximal end 52 to the midpoint of the distal end 51, the piezoelectric sensor 10 is symmetric about this axis. In this embodiment, shapes such as an isosceles triangle may be desirable. In other embodiments, the piezoelectric sensor 10 may not taper along its entire length. For example, as shown in FIG. 4, the piezoelectric sensor 10 may be formed as a hexagon, where the sides of the piezoelectric sensor 10 extending from the proximal end 52 toward the distal end 51 extend parallel to one another for a first distance. After this first distance, the piezoelectric sensor 10 may then taper, terminating in a shorter distal end 51. Thus, the piezoelectric sensor 10 may be a hexagon in this embodiment. In other words, the piezoelectric sensor 10 may not taper through its entire length, but may taper along at least a portion of its length. In other embodiments, the tapered sides may come together at a point so that the piezoelectric sensor 10 is a pentagon. In other embodiments, the piezoelectric sensor 10 may resemble a rounded triangle or a rounded pentagon, where the distal end 51 does not end in a point, but rather, in a rounded tip.

Thus, in these embodiments, the distal end 51 is smaller in the width direction than the proximal end 52. Further, in certain embodiments, the maximum width is at the proximal end 52.

In certain embodiments, the width of the piezoelectric sensor 10 at the proximal end 52 may be about 3-4 mm, and the length from the proximal end 52 to the distal end 51 may be 3-4 mm.

Note that the flex printed circuit board 25 is longer in the length direction than the piezoelectric sensor 10, such that the piezoelectric sensor 10 only covers a portion of the flex printed circuit board 25.

FIG. 4 also shows the various components that make up the piezoelectric sensor 10 and flex printed circuit board 25.

The flex printed circuit board 25 extends to the distal end 51 of the piezoelectric sensor 10. The flex printed circuit board 25 may be about 100 μm thick and may be made of polyimide. In this embodiment, the piezoelectric sensor 10 comprises two pieces of piezoelectric material; a top sensor 11 and a bottom sensor 12.

The top sensor 11 and the bottom sensor 12 may have the same dimensions. The piezoelectric material may be any suitable material, such as PVDF (polyvinylidene difluoride). The thickness of each sensor may be about 50 μm. These two sensors 11, 12 are poled in opposite directions, such that a bend in one direction creates opposite voltage responses in the two sensors. In other words, when the top of the piezoelectric sensor 10 is pushed downward, one of the sensors 11,12 will generate a positive voltage and the other sensor will generate a negative voltage.

A portion of the bottom sensor 12, at the proximal end 52, is disposed on the support 23, while another portion of the bottom sensor 12 extends from the support 23, so as to be free to bend. In another embodiment, the top sensor 11 is disposed on the support 23.

A ground shield 15 is located on the exposed surfaces of the top sensor 11 and the bottom sensor 12. In some embodiments, the ground shield 15 may be 100-200 nm of sputter coated metal.

Additionally, sputter coated metal may also be applied to both surfaces of the flex printed circuit board 25 to form the positive electrode 13 and the negative electrode 14. The sputter coated metal may be copper, nickel, gold, titanium, other suitable metals or a combination thereof. The electrodes may also be 100-200 nm in thickness.

An adhesive 18 may be disposed between the sensors 11, 12 and the flex printed circuit board 25. The adhesive 18 may be an epoxy having a thickness of 5-10 μm. In some embodiments, the adhesive 18 may be conductive, such as silver epoxy. In other embodiments, the adhesive may be non-conductive.

Thus, the device is symmetric in the thickness direction, including a flex printed circuit board 25 at the center, with electrodes 13, 14 disposed on opposite surfaces of the flex printed circuit board 25. Adhesive 18 coats the exposed surface of the electrodes 13, 14, and the sensors 11, 12 are disposed on the adhesive 18. Finally, ground shields 15 are disposed on the exposed surfaces of the sensors 11, 12. Thus, in order from top to bottom, the assembly comprises a ground shield 15, a top sensor 11, adhesive 18, a positive electrode 13, a flex printed circuit board 25, a negative electrode 14, adhesive 18, a bottom sensor 12 and a ground shield 15.

As best seen in FIG. 5A, an insulating material is used to create an insulating layer 19. The insulating layer 19 may be located between the ends of the sensors 11, 12 and the flex printed circuit board 25, and may cover at least a portion of the pads 16a on the flex printed circuit board 25 that are attached to the electrodes 13, 14. The insulating layer 19 may also overlap a portion of the pads 16 that are used for ground contacts. A conductive ink 27 may be applied to the exposed surface of the insulating layer 19 so as to electrically connect the ground shield 15 and the pads 16. Note that the conductive ink 27 does not contact the pads 16a.

Note that the pads 16a to which the electrodes 13, 14 are attached are not in electrical contact with the pads 16 to which the ground shield 15 is attached. In some embodiments, solder mask is used to prevent shorting to the ground shield 15. In this way, at least three signals are carried by the flex printed circuit board 25; a first signal from the positive electrode 13, a second signal from the negative electrode 14 and ground. In some embodiments, the first signal and the second signal are on opposite surfaces of the flex printed circuit board 25.

Note that the support 23 extends beyond the proximal end 52 of the sensors 11, 12, but terminates before the distal end 51 of the sensors 11, 12.

FIG. 5B shows a cross-section of the piezoelectric sensor 10 and the flex printed circuit board 25 according to another embodiment. The flex printed circuit board 25 and the sensors 11, 12 are as described above.

A conductive coating, such as copper, nickel or a combination thereof, is applied to the exposed surfaces of the top sensor 11 and the bottom sensor 12 and serves as a ground shield 15. In certain embodiments, the factory evaporation-coated copper-nickel layer on the sensors 11, 12 may act as the ground shield 15.

A layer of conductive epoxy, such as silver epoxy, is disposed between the top sensor 11 and the flex printed circuit board 25 and serves as the positive electrode 13. A second layer of conductive epoxy is disposed between the bottom sensor 12 and the flex printed circuit board 25 and serves as the negative electrode 14.

Pads 16a disposed on the flex printed circuit board 25 are used to electrically connect the positive electrode 13 and the negative electrode 14 to traces on the flex printed circuit board 25. Additionally, a conductive tape, such as copper tape 17, is used to electrically connect the ground shield 15 to pads 16 disposed on the flex printed circuit board 25. Note that the pads 16a to which the electrodes are attached are not in electrical contact with the pads 16 to which the copper tape 17 is attached. In this way, at least three signals are carried by the flex printed circuit board 25; a first signal from the positive electrode 13, a second signal from the negative electrode 14 and ground. In some embodiments, the first signal and the second signal are on opposite surfaces of the flex printed circuit board 25.

FIG. 5C shows a cross-sectional view of another embodiment. This embodiment is similar to that shown in FIG. 4 and FIG. 5A. However, in this embodiment, the top sensor and the bottom sensor are a plurality of piezoelectric layers 50a-50f disposed on each side of the flex printed circuit board 25.

In some embodiments, the top sensor comprises a first plurality of piezoelectric layers 50a-50c disposed on the first surface of the flex printed circuit board 25, while the bottom sensor comprises a second plurality of piezoelectric layers 50d-50f disposed on the second surface of the flex printed circuit board 25. In some embodiments, the first plurality is the same number as the second plurality. While FIG. 5C shows 3 piezoelectric layers disposed on each surface of the flex printed circuit board 25, the disclosure is not limited to this number.

In certain embodiments, all of the piezoelectric layers 50a-50f are the same size and shape, although other embodiments are also possible.

In certain embodiments, both surfaces of each piezoelectric layer 50a-50f are coated with a conductive material to form electrodes 55a-551. This conductive material may be as described above. The conductive material on the outer surface of the outermost piezoelectric layers 50a, 50f is used to provide ground shields 15.

In some embodiments, a non-conductive adhesive 18 is used to affix adjacent piezoelectric layers 50a-50f to each other. In this way, the electrodes on opposite sides of the adhesive 18 are electrical isolated from one another. This configuration may be used when all of the piezoelectric layers in the first plurality are poled in the same manner, such that a bending induces a charge having the same polarity in each piezoelectric layer in the first plurality. Likewise, all of the piezoelectric layers in the second plurality may also be poled in the same manner, such that a bending induces a charge having the same polarity in each piezoelectric layer in the second plurality. In certain embodiments, the polarity of the charge induced in the first plurality is the opposite of the polarity of the charge induced in the second polarity. In this embodiment, each electrode is in communication with a pad on the flex printed circuit board 25. This may be done by incorporating wires in the insulating layer 19 or some other way.

In another embodiment, adjacent piezoelectric layers may be poled in an alternating fashion, such that two adjacent piezoelectric layers are poled in the opposite direction. In this embodiment, a conductive epoxy may be used to affix two adjacent piezoelectric layers together. This conductive epoxy serves electrically connect the bottom electrode on one piezoelectric layer with the top electrode of the adjacent piezoelectric layer such that they are effectively a single shared electrode. In this embodiment, each electrode may be in communication with a pad on the flex printed circuit board 25. This may be done by incorporating wires in the insulating layer 19 or some other way.

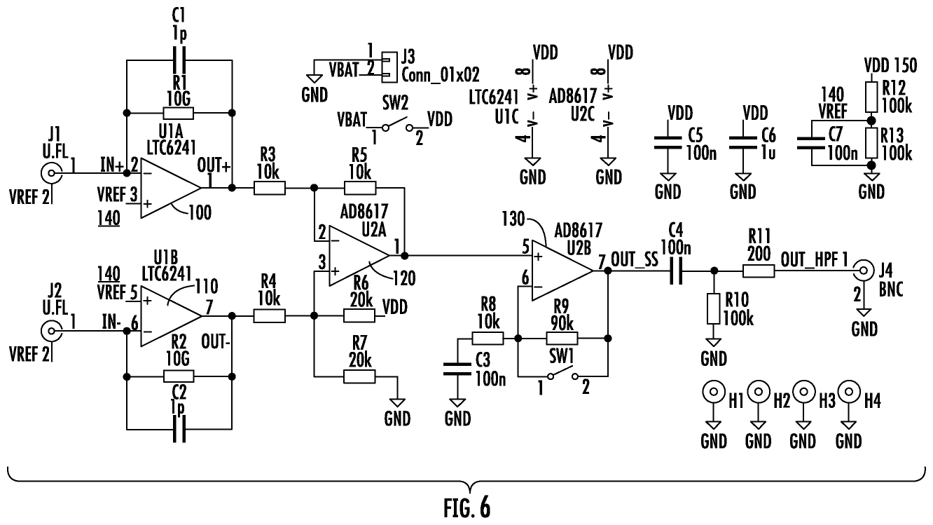

FIG. 6 shows a schematic of the amplifier 20 according to one embodiment. The amplifier is designed to take advantage of the differential signals provided by the positive electrode 13 and the negative electrode 14.

As shown on the right side, a reference voltage 140 is created by dividing the input voltage (VDD) 150 using resistors R12 and R13. In this embodiment, R12 and R13 have the same value such that the reference voltage 140 is of the input voltage 150.

This reference voltage 140 is used as the positive input to input opamps 100, 110. Input opamp 100 is in communication with the positive electrode 13, while input opamp 110 is in communication with the negative electrode 14. The input opamps 100, 110 serve to convert the charge on the electrodes 13, 14 into a voltage. In certain embodiments, the input opamps 100, 110 are based on the LTC6240, which has excellent voltage and current noise properties. The layout may also include a guard ring to protect the high impedance inputs from stray parasitic resistance and board currents. The outputs of these input opamps 100, 110 may ideally be two voltages that can be expressed as V_{ref}+/−Vₛₑₙₛₒᵣ, wherein V_{ref} is the reference voltage and Vₛₑₙₛₒᵣ is the magnitude of the signal experienced by the two sensors 11, 12. Difference opamp 120 is used to convert the differential input into a single ended voltage. Opamp 130 is used as part of an optional 20 dB gain stage. In certain embodiments, this gain stage may be omitted. The output from the amplifier 20 may then be used in the signal processing circuits described in FIG. 2. This combination of piezoelectric sensor 10 and amplifier 20 has been able to achieve an RMS noise floor over the audible bandwidth (100 Hz to 20 kHz) equivalent to a deflection of less than 50 pm.

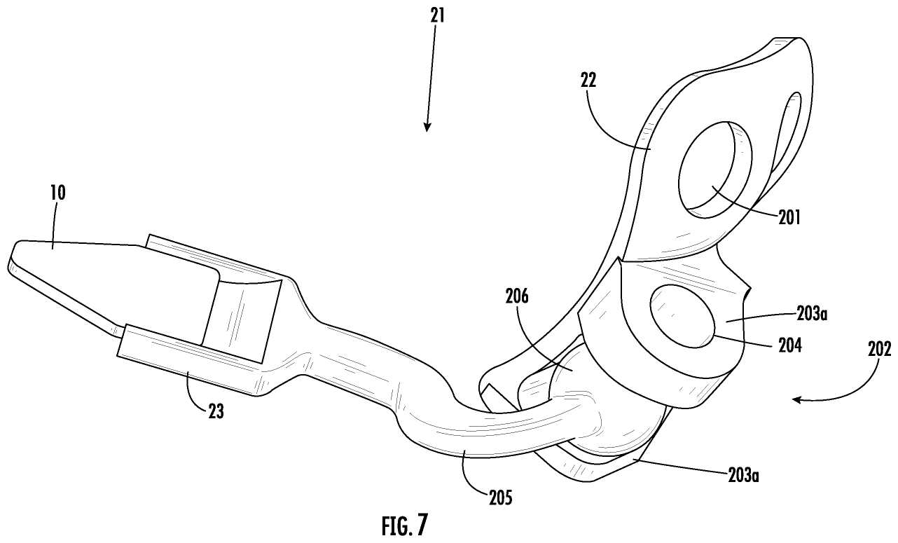

Having described the structure of the piezoelectric sensor 10, a specific embodiment of the platform 21, with the attached piezoelectric sensor 10, is shown in FIG. 7. In this embodiment, the anchor 22 and the support 23 are separate components. Specifically, the anchor 22 is designed to be attached to the anterior wall of the mastoid cavity. As such, it includes one or more anchor holes 201. These holes are dimensioned so that a screw may be used to affix the anchor 22 to the anterior wall. The anchor 22 also includes a ball joint 202. The ball joint 202 comprises two protruding tabs 203a, 203b that are spaced apart. One of the protruding tabs 203a includes a threaded hole 204, that is adapted to accommodate a set screw (not shown). The set screw may be a M2 screw in some embodiments.

The support 23 is used to hold the piezoelectric sensor 10. The support 23 is at the distal end of an arm 205. The support 23 may have a shovel type shape into which the piezoelectric sensor 10 is disposed. More specifically, the support 23 may include a bottom wall and two side walls that define an open box into which the piezoelectric sensor 10 may be installed. In some embodiments, piezoelectric sensor is glued to the support 23. As explained above, the piezoelectric sensor 10 is positioned on the support 23 such that it is capable of bending.

The arm 205 may have a meandered shape to better fit within the ear canal. The proximal end of the arm 205 includes a ball 206. In some embodiments, the ball 206 may be 2.5 mm in diameter. The ball 206 fits between the two protruding tabs 203a, 203b on the anchor 22. After the ball 206 is placed in the ball joint 202, the set screw may be tightened.

In some embodiments, the anchor 22 and the arm 205 are made of titanium.

By separating the platform 21 into two components connected using a ball joint 202, the implantation of the device may be simplified. Further, the ball joint 202 allows a large degree of freedom in several directions to adapt to different anatomies.

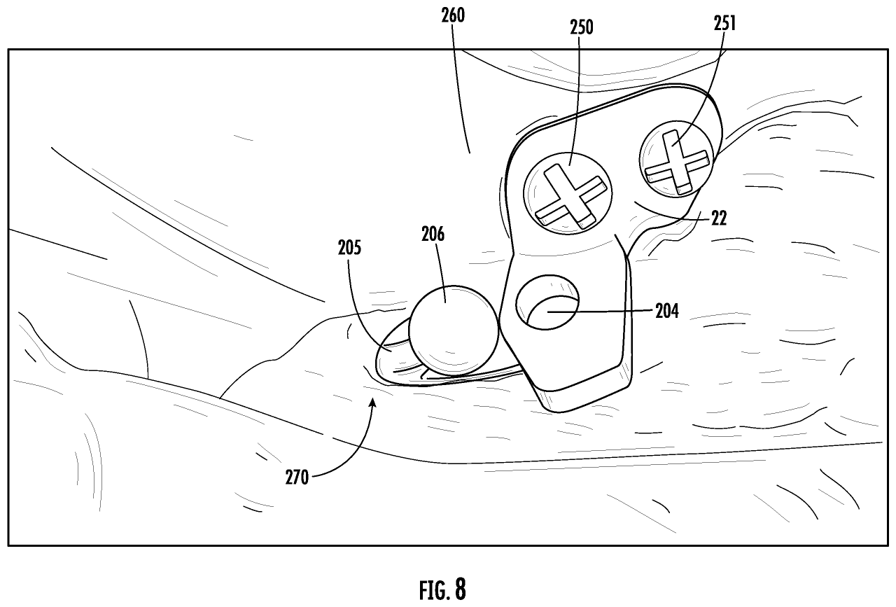

FIG. 8 shows a portion of the implantable auditory aid device, which comprises the platform 21 and the piezoelectric sensor 10, being implanted into a human ear. As noted above the platform 21 is formed as two separate components, the anchor 22 and the support 23 with the arm 205. The anchor 22 is intended to be attached to the anterior wall of the mastoid cavity. To access this area, a mastoidectomy is performed first, and then a hole is drilled through the facial recess. The mastoidectomy drills through spongy bone inside the mastoid bone to create the mastoid cavity (behind the ear) and the facial recess is a narrow piece of hard bone that must be drilled through to access the middle ear cavity.

Then, a first hole may be predrilled in the anterior wall of the mastoid cavity. The anchor 22 may then be attached to the bone 260 by a first screw 250 passing through anchor hole 201. Using the attached anchor 22 as a template, a second hole may be predrilled in the bone 260. The second screw 251 is then used, passing through the second anchor hole 201 and into the bone 260. Both screws may be positioned on the lateral aspect of the mastoid cavity wall to enable right angle screwing. At this point, the set screw may be partially inserted into the threaded hole 204. Note that, at the time, only the anchor 22 has been implanted. The support 23 and arm 205 are not attached to the anchor 22 at this time.

The piezoelectric sensor 10 is mounted to the support 23. Holding the arm 205, the piezoelectric sensor 10 is then inserted through the facial recess 270 in the patient. The ball 206 is placed in the ball joint 202 and the set screw is tightened. The arm 205 is positioned so that the piezoelectric sensor 10 is contacting the umbo 26.

Afterwards, the positioning of the implantation may be verified. In one embodiment, an endoscope is used to determine whether the piezoelectric sensor 10 is contacting the umbo 26. In another embodiment, a predetermined sound may be delivered to the ear canal, and the output from the piezoelectric sensor 10 may be measured.

The signals from the flex printed circuit board 25 may be passed to an external component using small coaxial cables or twisted wires. In certain embodiments, the arm 205 may be hollow such that the connections may be encased in the arm 205 and exit at or near the ball 206.

The present system has many advantages. The differential signals and differential amplifier are important in reducing electromagnetic interference. Layering two layers of PVDF on either side of a flex printed circuit board has multiple design advantages. This solution provides a straightforward way to connect the piezoelectric sensor 10 to the amplifier 20. The current design uses two U.FL connectors soldered to the flex printed circuit board 25 to connect to the amplifier 20. There are a wide range of potential options for connecting the flex printed circuit board 25 to the amplifier 20, ranging from directly inserting the flex printed circuit board 25 into a ribbon cable connector to integrating the piezoelectric sensor 10 with the amplifier 20 using a rigid-flex printed circuit board. The double layer allows for a fully shielded differential cantilever to be realized without compromising the mechanical impedance or adding undue parasitic capacitance, both of which damage sensor performance. Placing the PVDF on both sides of the flexible substrate also allows the device to harvest energy more efficiently than a single layer, as all parts of the device under high stress are piezoelectric.

Many current designs for implantable microphones suffer from poor mechanical impedance matching between the ear and the sensor, which decreases sensitivity. The present sensor is designed to have a mechanical impedance close to the mechanical impedance of the ear drum, and this impedance can be fine tuned by adjusting the length of the cantilever. Achieving a good mechanical impedance match with the ear drum is possible because the piezoelectric sensor 10 is constructed of PVDF, which is much softer than other common piezoelectric materials. This sensor design also has a very linear sensitivity and mechanical impedance, allowing for easier installation and greater dynamic range.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An implantable auditory aid device, comprising:
a piezoelectric sensor; and
a platform having an anchor to attach to a subject's ear bone and a support to hold the piezoelectric sensor such that the piezoelectric sensor is cantilevered; wherein the piezoelectric sensor comprises:
a flex printed circuit board;
a top sensor disposed on a first surface of the flex printed circuit board; and
a bottom sensor disposed on an opposite second surface of the flex printed circuit board; the top sensor and bottom sensor made of a piezoelectric material.

2. The implantable auditory aid device of claim 1, wherein the top sensor and the bottom sensor are shorter in a length direction than the flex printed circuit board and each have a proximal end near an attachment to the support and a distal end, wherein the distal end of one of the sensors is adapted to contact an umbo in the subject's ear.

3. The implantable auditory aid device of claim 2, wherein the proximal end is wider than the distal end.

4. The implantable auditory aid device of claim 3, wherein the top sensor and the bottom sensor are each shaped as a triangle, trapezoid or pentagon.

5. The implantable auditory aid device of claim 3, wherein the top sensor and the bottom sensor are each shaped as a hexagon.

6. The implantable auditory aid device of claim 2, wherein silver epoxy is disposed between the top sensor and the first surface of the flex printed circuit board to form a positive electrode; silver epoxy is disposed between the bottom sensor and the opposite second surface of the flex printed circuit board to form a negative electrode; and the positive electrode and the negative electrode are connected to pads on the flex printed circuit board.

7. The implantable auditory aid device of claim 6, wherein an exposed surface of the top sensor and the exposed surface of the bottom sensor are covered with a conductive coating, which serves as a ground plane and is connected to a ground pad on the flex printed circuit board.

8. The implantable auditory aid device of claim 6, wherein signals from the positive electrode and the negative electrode are used as inputs to a differential amplifier.

9. The implantable auditory aid device of claim 2, wherein a conductive layer is evaporated on the first surface of the flex printed circuit board to form a positive electrode and the conductive layer is evaporated on the opposite second surface of the flex printed circuit board to form a negative electrode; wherein the top sensor and the bottom sensor are each attached to the conductive layer using an adhesive and the positive electrode and the negative electrode are connected to pads on the flex printed circuit board.

10. The implantable auditory aid device of claim 9, wherein an exposed surface of the top sensor and the exposed surface of the bottom sensor are covered with a conductive coating, which serves as a ground plane and is connected to the flex printed circuit board.

11. The implantable auditory aid device of claim 9, wherein signals from the positive electrode and the negative electrode are used as inputs to a differential amplifier.

12. The implantable auditory aid device of claim 2, wherein a conductive layer is sputtered on the first surface of the flex printed circuit board to form a positive electrode and the conductive layer is sputtered on the opposite second surface of the flex printed circuit board to form a negative electrode; wherein the top sensor and the bottom sensor are each attached to the conductive layer using an adhesive and the positive electrode and the negative electrode are connected to pads on the flex printed circuit board.

13. The implantable auditory aid device of claim 12, wherein an exposed surface of the top sensor and the exposed surface of the bottom sensor are sputtered with a conductive coating, which serves as a ground plane and is connected to the flex printed circuit board using a conductive ink.

14. The implantable auditory aid device of claim 12, wherein signals from the positive electrode and the negative electrode are used as inputs to a differential amplifier.

15. The implantable auditory aid device of claim 1, wherein the platform comprises:
the anchor, for attachment to the subject's ear bone; and
the support disposed at a distal end of an arm;
wherein the anchor and the support are separate components.

16. The implantable auditory aid device of claim 15, further comprising a ball joint disposed on the anchor and a ball disposed on a proximal end of the arm, wherein the arm is rigidly attached to the ball joint using a set screw.

17. The implantable auditory aid device of claim 16, wherein the anchor comprises one or more anchor holes, and the ball joint comprises a threaded hole.

18. A method of implanting the implantable auditory aid device of claim 17 in the subject's ear, comprising:
attaching the anchor to a bone in a mastoid cavity by inserting screws through the one or more anchor holes;
guiding the piezoelectric sensor through a facial recess of the subject, while the piezoelectric sensor is attached to the support; and
affixing the arm to the anchor by tightening a set screw in the threaded hole.

19. The method of claim 18, wherein after tightening the set screw, the piezoelectric sensor contacts an umbo.

20. The method of claim 18, further comprising inserting the set screw in the threaded hole prior to guiding the piezoelectric sensor.

21. The method of claim 19, wherein the positioning of the piezoelectric sensor is confirmed using an endoscope.

22. The method of claim 19, wherein the positioning of the piezoelectric sensor is confirmed by delivering a sound to an ear canal and monitoring an output of the piezoelectric sensor.

23. The implantable auditory aid device of claim 1, wherein the top sensor comprises a first plurality of piezoelectric layers stacked on the first surface of the flex printed circuit board; and the bottom sensor comprises a second plurality of piezoelectric layers stacked on the opposite second surface of the flex printed circuit board.

24. The implantable auditory aid device of claim 23, wherein a conductive layer is disposed on both surfaces of each piezoelectric layer, wherein the conductive layers serve as electrodes or ground layers.

25. The implantable auditory aid device of claim 24, wherein outputs from the electrodes disposed on the first surface of the flex printed circuit board are arranged in parallel such that charges induced on each of the first plurality of piezoelectric layers are summed.

26. The implantable auditory aid device of claim 24, wherein the conductive layer on a first surface of a piezoelectric layer is also the conductive layer on a second surface of an adjacent piezoelectric layer, and a conductive epoxy is used to affix the piezoelectric layer and the adjacent piezoelectric layer.

27. The implantable auditory aid device of claim 24, further comprising epoxy disposed between the conductive layer on a first surface of a piezoelectric layer and the conductive layer on a second surface of an adjacent piezoelectric layer.

28. The implantable auditory aid device of claim 23, wherein the first plurality of piezoelectric layers is equal to the second plurality of piezoelectric layers.
